(19) United States
(12) Patent Application Publication
(10) Pub. No.: US 2019/0043747 A1
(43) Pub. Date: Feb. 7, 2019

(54) FLEXIBLE CIRCUIT INTERCONNECT STRUCTURE AND METHOD OF MAKING SAME

(71) Applicant: Intel Corporation, Santa Clara, CA (US)

(72) Inventors: Pramod MALATKAR, Chandler, AZ (US); Richard J. HARRIES, Chandler, AZ (US); Robert L. SANKMAN, Phoenix, AZ (US); David C. MCCOY, Phoenix, AZ (US)

(21) Appl. No.: 16/075,095

(22) PCT Filed: Apr. 2, 2016
(86) PCT No.: PCT/US16/25776

§ 371 Date: Aug. 2, 2018

(51) Int. Cl. H01L 21/683; H01L 23/31; H01L 23/48; H01L 23/538; H01L 21/56; H01L 23/00

(52) U.S. Cl. CPC H01L 21/6835; H01L 23/3121; H01L 23/48; H01L 2224/45147; H01L 21/568; H01L 24/45; H01L 24/83; H01L 23/5387

(57) ABSTRACT

Techniques and mechanisms for providing flexible packaged circuit structures. In an embodiment, a flexible circuit device includes first and second conductive contacts and an interconnect that is coupled between such conductive contacts. While the flexible circuit device is in a baseline (“flat”) configuration, a first side of the flexible circuit device extends at least in part in a flat plane, and a portion of the interconnect includes a point that, with respect to a distance from the flat plane, is a maximum or a minimum of the interconnect. A mold compound of a flexible package encapsulates the portion of the interconnect. In another embodiment, a range spanned by the interconnect along a line orthogonal to the flat plane is at least two times an average height of the interconnect.

### BACKGROUND

### 1. Technical Field

Embodiments described herein generally relate to flexible interconnect structures and more particularly, but not exclusively, to wearable electronic devices.

### 2. Background Art

End users have more electronic device choices than ever before. A number of prominent technological trends are currently afoot (e.g., mobile electronic devices, smaller electronic devices, increased user connectivity, etc.), and these trends are changing the electronic device landscape. Recently, a variety of different technologies have been demonstrated on bendable and/or stretchable substrates. Wearable electronic systems are just one type of technology that can benefit from the flexibility of circuit structures. Wearable electronic devices can be worn over clothes or directly on the skin of a user's wrist, arm, ankle, etc. Integrating electronics into clothing or accessories has been identified as a mechanism to augment sensing, communication, or entertainment. Such integrated electronics can be utilized to compliment a user's gaming experience, improve patient health monitoring, or provide readily available control functionality to a user.

Sources of increased demand for flexible circuitry solutions include recent developments in flexible OLED (Organic Light Emitting Diode), e-paper and other display technologies. As this demand continues to increase, there is expected to be a premium placed on the efficient exchange of signaling, voltages, etc. in highly bendable and/or stretchable circuit devices.

### BRIEF DESCRIPTION OF THE DRAWINGS

The various embodiments of the present invention are illustrated by way of example, and not by way of limitation, in the figures of the accompanying drawings and in which:

FIGS. 1A, 1B show cross-sectional views of respective flexible circuit devices each according to a corresponding embodiment.

FIG. 2 is a flow diagram illustrating elements of a method for providing a flexible circuit device according to an embodiment.

FIGS. 3A, 3B, 3C are cross-sectional views of structures formed by assembly processing according to an embodiment.

FIGS. 4A, 4B, 4C are cross-sectional views of structures formed by assembly processing according to an embodiment.

FIG. 5 shows a cross-sectional view of a flexible circuit device including an interconnect structure according to an embodiment.

FIG. 6 is a functional block diagram illustrating elements of a computer device according to an embodiment.

FIG. 7 is a functional block diagram illustrating elements of a computer system according to an embodiment.

### DETAILED DESCRIPTION

Embodiments discussed herein variously provide techniques and mechanisms for providing a bendable and/or stretchable interconnect of a flexible circuit device. A flexible circuit device, according to some embodiments, may be arranged in some baseline configuration (also referred to herein as a “reference configuration”) during which at least part of a first side of the flexible circuit device extends in a flat plane. At other times, such a flexible circuit device may be variously bent, stretched, twisted or otherwise deformed from such a reference configuration—e.g., wherein the flexible circuit device may be subsequently returned to the reference position or further deformed into any of various other configurations.

The flexible circuit device may include conductive contacts and an interconnect structure coupled to each of such conductive contacts—e.g., wherein the interconnect structure is coupled to communicate a signal, a supply voltage, a reference potential (e.g., a ground) and/or the like. While the flexible circuit device is in the baseline configuration, the interconnect structure may extend at least in part along a path which is parallel to the flat plane. Flexibility of the interconnect structure may be provided at least in part by one or more curves of the interconnect structure—e.g., where some or all of such one or more curves are each, at least in part, in a respective direction or plane that is orthogonal to the flat plane. For example, the interconnect structure may comprise a first portion that, while the flexible circuit device is in the baseline configuration, includes a maximum of the interconnect structure or a minimum of the interconnect structure. In this particular context, “maximum” and “minimum” are used herein to refer, respectively, to a largest distance (at least locally) from a flat plane and a smallest distance (at least locally) from a flat plane. More particularly, a maximum is a point which is a highest peak (at least locally) of an interconnect structure, where the height is determined relative to a flat plane over which the interconnect structure extends. Correspondingly, a minimum is a lowest point (at least locally) of an interconnect structure, relative to such a flat plane.

The technologies described herein may be implemented in one or more electronic devices. Non-limiting examples of electronic devices that may utilize the technologies described herein include any kind of mobile device and/or stationary device, such as cameras, cell phones, computer terminals, desktop computers, electronic readers, facsimile machines, kiosks, netbook computers, notebook computers, internet devices, payment terminals, personal digital assistants, media players and/or recorders, servers (e.g., blade server, rack mount server, combinations thereof, etc.), set-top boxes, smart phones, tablet personal computers, ultra-mobile personal computers, wired telephones, combinations thereof, and the like. Such devices may be portable or stationary. In some embodiments the technologies described herein may be employed in a desktop computer, laptop computer, smart phone, tablet computer, netbook computer, notebook computer, personal digital assistant, server, combinations thereof, and the like. More generally, the technologies described herein may be employed in any of a variety of electronic devices including a flexible package having circuit structures disposed therein.

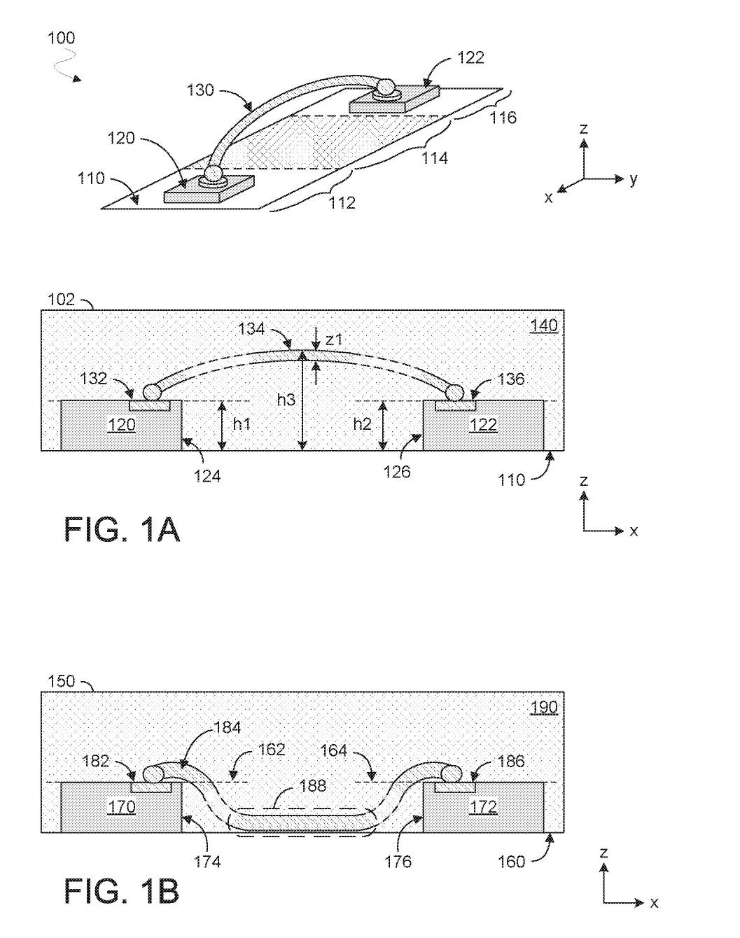

FIG. 1A illustrates elements of a device 100 including flexible circuit structures according to an embodiment. Device 100 is one example of an embodiment comprising circuit structures including two conductive contacts and an interconnect structure coupled to each such conductive contact, wherein some or all such circuit structures are disposed in a flexible package. At a time when a side of the flexible circuit device is positioned to extend in a flat plane (and/or upon manufacturing of the flexible circuit device), a portion of the interconnect structure may, with respect to the various distances of different points from the flat plane, include a maximum of the interconnect structure or a minimum of the interconnect structure. For example, the portion may include a maximum point which—at least locally—is farther from the flat plane than any other point of the interconnect structure (or at least a surrounding portion thereof). Alternatively or in addition, the portion of the interconnect structure may include a minimum point which is (at least locally) closer to the flat plane than any other point of the interconnect structure (or at least a surrounding portion thereof). In an embodiment, a variation in height along an entire length of the interconnect structure is multiple times larger than an average cross-sectional thickness of the interconnect structure.

In the illustrative embodiment shown, device 100 includes conductive contacts 132, 136 and an interconnect structure 134 coupled between conductive contacts 132, 136. Some or all of interconnect structure 134 and conductive contacts 132, 136 (or other coupling structures of device 100) may variously include copper, gold, silver, nickel and/or any of a variety of other metals adapted from conventional circuit interconnect techniques. Interconnect structure 134 may include a wire that forms respective bonds (e.g., including ball bonds or wedge bonds) to conductive contacts 132, 136. Although some embodiments are not limited in this regard, such a wire have a thickness (e.g., diameter) that is in a range from 250 microns (μm) to 400 μm. However, significantly thicker (or, alternatively, thinner) interconnect structures may be used. For example, an interconnect structure may have a diameter as low as approximately 20 μm (e.g., ±10%), in other embodiments. For many applications, an interconnect structure having a diameter in a range of 100-400 μm may be acceptable. Some embodiments may include an interconnect having a diameter that is more than 400 μm—e.g., for wearable applications with relatively few and/or low data rate I/O signals. In some embodiments, interconnect structure 134 may instead include a flat, braided copper wire (or other such flexible braided conductor) that is variously soldered to each of conductive contacts 132, 136.

A flexible package 140 may adjoin, extend around and/or otherwise encapsulate some or all of conductive contacts 132, 136 and interconnect structure 134. Flexible package 140 may comprise an elastomer (e.g., including thermoplastic polyurethane) and/or any of a variety of mold compounds that, for example, are adapted from conventional techniques for forming a flexible package structure. In the perspective view of device 100 shown in FIG. 1A, structures of device 100 are illustrated in relation to an xyz coordinate system. The cross-sectional side view 102 of device 100 shows structures in an x-z plane of the xyz coordinate system. Flexible package 140 is omitted from the perspective view of device 100 to avoid obscuring certain features of interconnect structure 130 and contacts 132, 136.

Flexibility of package material 140, interconnect structure 130 and/or other structures of device 100 may accommodate an (at least temporary) physical manipulation and/or other positioning such that a side 110 of device 100 extends at least in part in a flat plane—e.g., wherein regions 112, 114, 116 of side 110 each extend in the flat plane. Some or all of side 110 may be formed at least in part, for example, by flexible package 140 and/or structures encapsulated by flexible package 140. By way of illustration and not limitation, side 110 may include a side portion of flexible package 140 and the respective sides of insulator structures 120, 122. However, side 110 may be formed by more, fewer and/or differently arranged structures of device 100, in different embodiments. Although some embodiments are not limited in this regard, conductive contacts 132, 136 may each be offset from side 110—e.g., by insulator structures 120, 122 having conductive contacts 132, 136 (respectively) variously formed therein or thereon. In another embodiment, one or both of conductive contacts 132, 136 extend to side 110.

Interconnect structure 130 may extend to provide a signal or voltage between conductive contacts 132, 136, where an exchange of the signal or voltage is at least partially (and in some embodiments, mostly) in a direction parallel to the flat plane—e.g., along the x-axis shown. In such an embodiment, a portion 134 of interconnect structure 130 may include, or be formed at least in part by, a bend or other curve in a direction that is orthogonal to the flat plane—e.g., wherein the curve changes a path of interconnect structure 130 at least partially (and in an embodiment, predominantly) toward a direction in parallel with the z-axis. Curving of interconnect structure 130 may result in portion 134 of interconnect structure 130 being at a (z-axis) height above the flat plane which is above the respective heights of conductive contacts 132, 136 or (in an alternative embodiment) which is below the respective heights of conductive contacts 132, 136. For example, portion 134 may extend above and across the region 114 to flexibly interconnect respective circuitry in regions 112, 116.

By way of illustration and not limitation, one distal end of interconnect structure 130 may be coupled to conductive contact 132 at a z-axis distance h1 from side 110. Alternatively or in addition, another distal end of interconnect structure 130 may be coupled to conductive contact 136 at a z-axis distance h2 from side 110—e.g., where h2 is equal to (or alternatively, different from) h1. In such an embodiment, a maximum at portion 134 may be offset from side 110 by a distance h3 which is more than h1 and more than h2. An overall z-axis range spanned by interconnect structure 130—e.g., the range represented by one of the difference values (h3−h1) and (h3−h2)—may be multiple times an average cross-sectional height of interconnect structure 130. One example of a cross-sectional height is represented by the illustrative distance z1 shown at portion 134. In some embodiments, the range spanned by interconnect structure 130 is two or more times larger than the average cross-sectional height—e.g., wherein the range is three or more times (and in some embodiments, five times or more) larger than the average cross-sectional height. The range may be ten or more times larger than the average cross-sectional height of interconnect structure 130, for example.

In one embodiment, insulator structure 120 extends to a plane 124 which is orthogonal to the flat plane (and to side 110)—e.g., wherein a sidewall of insulator structure 120 extends at least partially in plane 124. Alternatively or in addition, insulator structure 122 may similarly extend to a plane 126 which is orthogonal to side 110—e.g., wherein a sidewall of insulator structure 122 extends at least partially in plane 126. In such an embodiment, interconnect structure 130 may extend through each of planes 124, 126 to extend over a region (e.g., region 114) of side 110 which does not include one or more structures. For example, interconnect structure 130 may extend between structures which are variously disposed over regions 112, 116, but which do not extend into region 114. Alternatively or in addition, interconnect structure 130 may extend over one or more other structures which are disposed over region 114—e.g., where such one or more other structures do not extend into region 112 and/or into region 116.

FIG. 1B shows a cross-sectional view of a flexible circuit device 150 according to another embodiment. Flexibility of structures in device 150 may accommodate an at least temporary configuration of device 100 such that a side 160 of device 150 extends, at least in part, in a flat plane. In the illustrative embodiment shown, device 150 includes conductive contacts 182, 186, a flexible package 190 and insulator structures 170, 172 that (for example) provide functionality corresponding to that of conductive contacts 132, 136, flexible package 140 and insulator structures 120, 122, respectively.

Device 150 is an example of an embodiment wherein a portion of an interconnect structure includes an at least local minimum point. For example, an interconnect structure 184 may be wire bonded or otherwise coupled to conductive contact 182 in a plane 162, and to conductive contact 182 in a plane 164. Planes 162, 164 may have the same or different respective offsets from side 160, in various embodiments. A portion 188 of interconnect structure 184 may extend below plane 162 and below plane 164, wherein a point in portion 188 is a relatively closest point to side 160 (e.g., where the point is at side 160). For example, portion 188 may be disposed at least in part between respective sidewalls 174, 176 of insulator structures 170, 172. In some embodiments, a height (z-axis) range spanned by interconnect structure 184 is two or more times larger than an average cross-sectional height of interconnect structure 184—e.g., wherein the height range is three or more times (and in some embodiments, five times or more) larger than the average cross-sectional height.

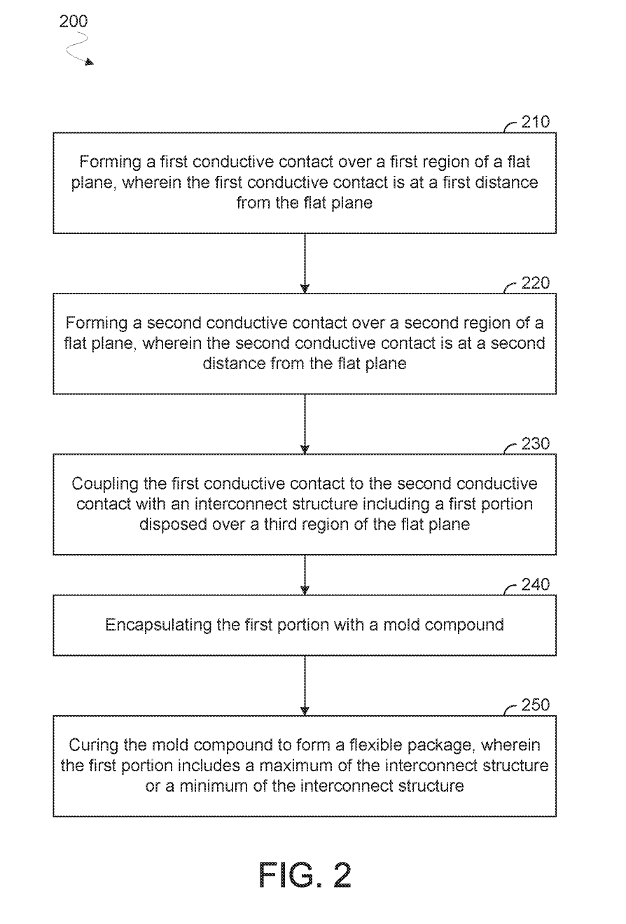

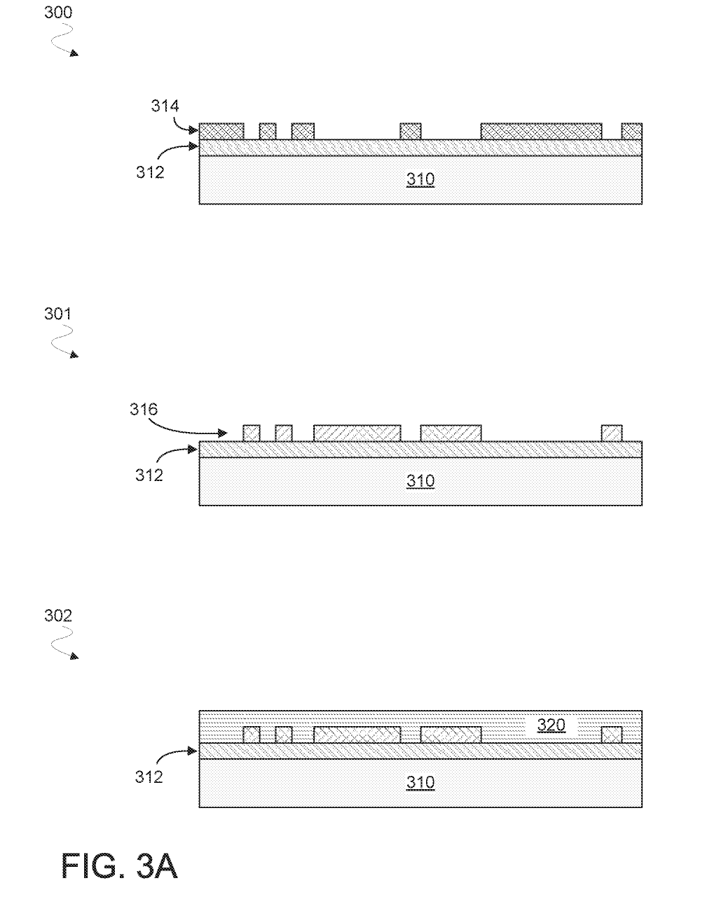

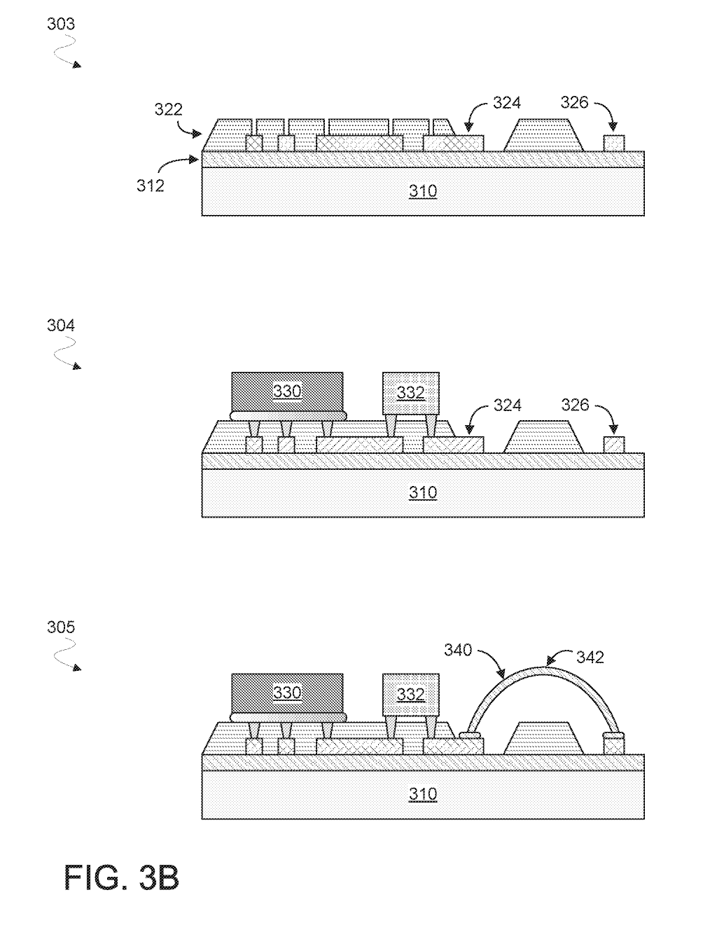

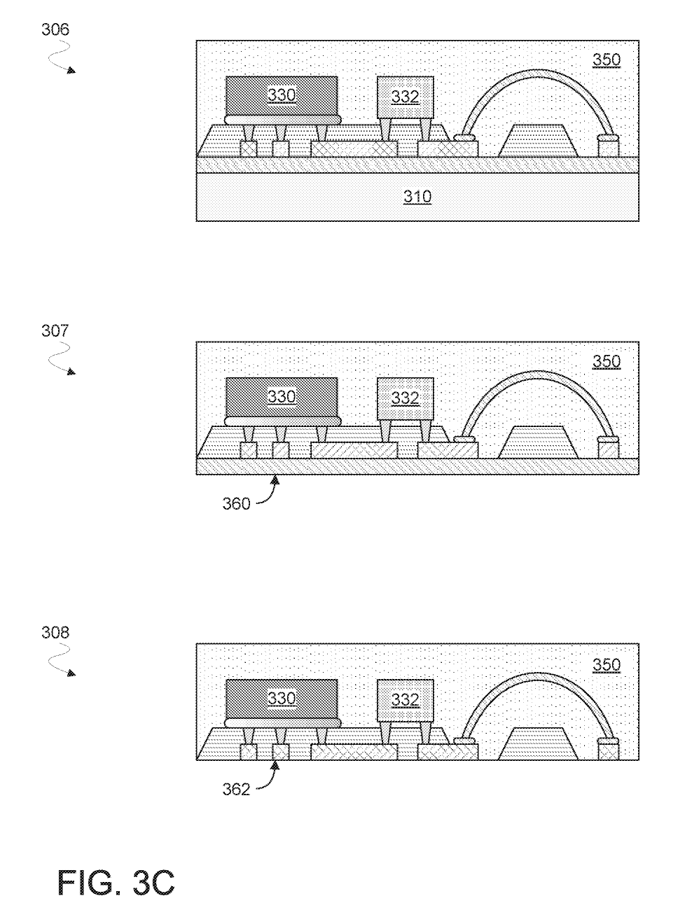

FIG. 2 illustrates elements a method 200 to package flexible circuit structures according to an embodiment. Method 200 is one example of processing that, for example, results in flexible circuitry having some or all of the features of device 100. To illustrate certain features of various embodiments, method 200 is described herein with reference to structures formed by processing stages 300-308—as shown in FIGS. 3A-3C—for the formation of a packaged circuit device. However, such discussion may be extended to apply to any of a variety of additional or alternative structures, according to different embodiments. Moreover, the processing represented by stages 300-308 may include additional and/or alternative operations to those of method 200, in some embodiments.

In an embodiment, method 200 includes, at 210, forming a first conductive contact over a first region of a first flat plane, wherein the first conductive contact is at a first distance from the first flat plane. Method 200 may further comprise, at 220, forming a second conductive contact over a second region of a first flat plane, wherein the second conductive contact is at a second distance from the first flat plane. The forming of respective contacts at 210 and 220 may be performed simultaneously, for example. An example of the various forming at 210 and at 220, according to one embodiment, is illustrated by stages 300-304.

Referring now to stage 300, a release layer 312 may be formed on a side of a substrate 310 comprising one or more core layers. Substrate 310 may comprise plastic, epoxy, glass, metal and/or any of a variety of other handling layer materials adapted, for example, from conventional structures for fabricating, assembling and/or otherwise positioning circuit structures for packaging. Release layer 312 may comprise a peelable film (e.g., having a prepreg structure) and/or any of a variety of other structures that facilitate a subsequent separation of circuit structures and/or packaging material from substrate 310. Release layer 312 may include one or more plastic, silicone and/or other suitable materials—e.g., used in conventional release structures—configured to be peeled, delaminated or otherwise separated from one or more core layers of substrate 310. For example, release layer 312 may include a synthetic polymer such as polytetrafluoroethylene, polyimide or the like. In an embodiment, release layer 312 includes or is otherwise treated with a releasing agent that can be chemically, thermally or otherwise activated to induce separation from an adjoining structure.

At stage 300, patterned mask 314 (e.g., comprising any of a variety of conventional dry mask film materials) may be formed on release layer 312. As shown at stage 301, patterned mask 314 may be stripped or otherwise removed after metallization processes (e.g., including electroplating) to form patterned metal layer 316 on release layer 312. Patterned metal layer 316 may include structures that are to function as respective conductive contacts of a hardware interface or, alternatively, are to facilitate coupling of such conductive contacts at an exterior of a final packaged device resulting from the processing of stages 300-308.

Referring now to stage 302, a layer 320 of one or more insulator materials (e.g., including any of various solder resist materials, photoimageable dielectrics and/or the like) may be deposited over patterned metal layer 316. Additional pattern processing—e.g., including mask, exposure, development, cure and/or other operations adapted, for example, from conventional lithographic techniques—may be performed to generate patterned insulator layer 322 from layer 320, as shown in stage 303. In some embodiments, substrate 310 is formed by cutting of a larger substrate into strips (not shown)—e.g., where such cutting is performed after formation of patterned insulator layer 322. Patterned insulator layer 322 may expose contacts 324, 326 of patterned metal layer 316 for subsequent coupling to one another via an interconnect structure 340—e.g., wherein contacts 324, 326 include the first contact and second contact variously formed at 210 and at 220.

Although some embodiments are not limited in this regard, patterned insulator layer 322 may further expose portions of patterned metal layer 316 for subsequent coupling to other respective circuit structures. By way of illustration and not limitation, circuit components 330, 332 may be variously soldered, bonded or otherwise coupled, at stage 304, to respective contacts of patterned metal layer 316. Although certain embodiments are not limited in this regard, some or all of circuit components 330, 332 may be variously coupled each to patterned insulator layer 332 via an underfill material that, for example, provides an interface to accommodate differences between the respective coefficients of thermal expansion for adjoining materials. Any of a variety of organic polymers, inorganic fillers and/or other conventional underfill materials may be adapted for use in some embodiments.

Circuit components 330, 332 may include any of a variety of passive circuit elements and/or active circuit elements. By way of illustration and not limitation, circuit components 330, 332 may include one or more distinct capacitors and/or inductors. Alternatively or in addition, circuit components 330, 332 may include one or more IC chips including processor logic, memory resources, controller circuitry and/or any of a variety of other types of integrated circuity. Such one or more IC chips may include a system-on-chip (SoC), for example.

In an embodiment, method 200 includes, at 230, coupling the first conductive contact to the second conductive contact with an interconnect structure including a first portion which extends over a third region of the first flat plane, the third region between the first region and the second region. Referring again to the example embodiment illustrated at stage 304, patterned insulator layer 322 may further expose contacts 324, 326 of patterned metal layer 316 for subsequent coupling to one another via an interconnect structure 340. Coupling of contacts 324, 326 to one another may include, at 305, wire bonding (or otherwise coupling) interconnect structure 340—e.g., wherein a shape of interconnect structure 340 is curved prior to or during such wire bonding. In other embodiments, the coupling at 230 includes performing metal deposition to fabricate the interconnect structure.

Method 200 may further comprise, at 240, encapsulating the first portion with a mold compound and, at 250, curing the mold compound to form a flexible package. With respect to a distance from the first flat plane, the first portion may include a maximum of the interconnect structure or a minimum of the interconnect structure. For example, at stage 306, a mold compound 350 may be injection molded or otherwise disposed on or around a portion of interconnect structure 340 which includes a point 342. The point 342 may be a maximum (or in another embodiment, a minimum) with respect to distance from a flat side of release layer 312 or a plane extending in parallel with such a flat side. In an embodiment, the interconnect structure extends only partially through the mold compound along an axis orthogonal to the first flat plane—e.g., wherein a height range spanned by interconnect structure 340 does not extend to a top surface of mold compound 350.

Subsequently a flexible circuit device (including mold compound 350 and structures encapsulated thereby) may be separated from substrate 310. For example, substrate 310 may first be removed, at 307, to reveal a side 362 of release layer 312. Then, at 308, release layer 312 may be removed to reveal a side 360 of the flexible circuit device.

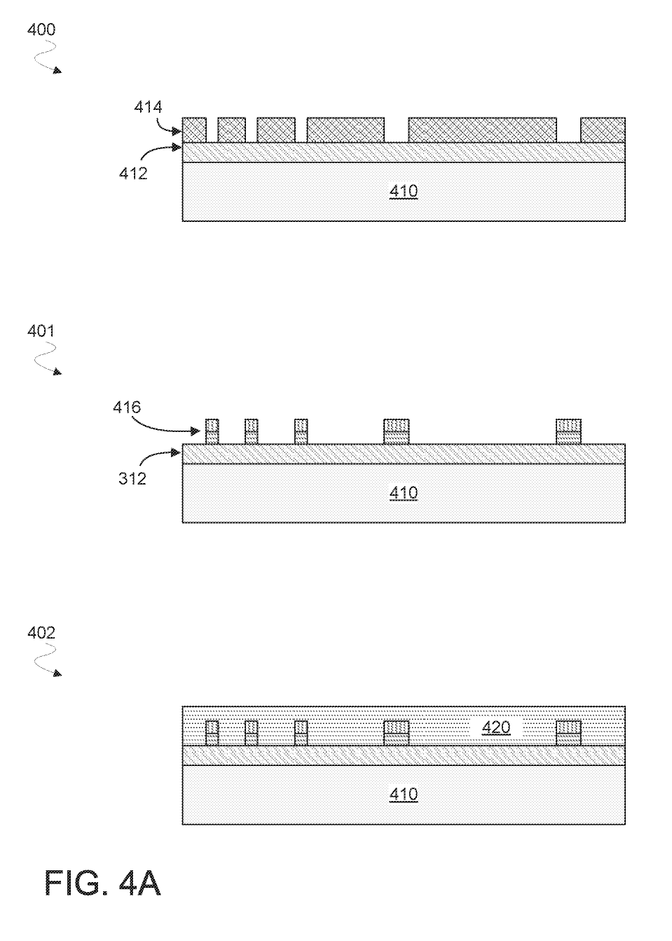

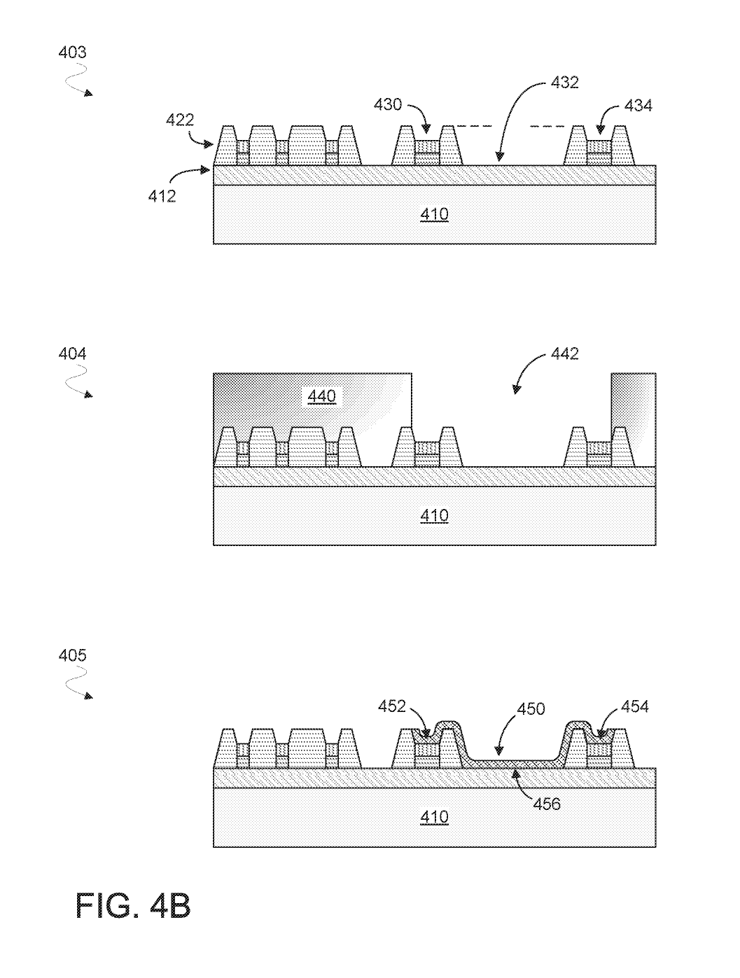

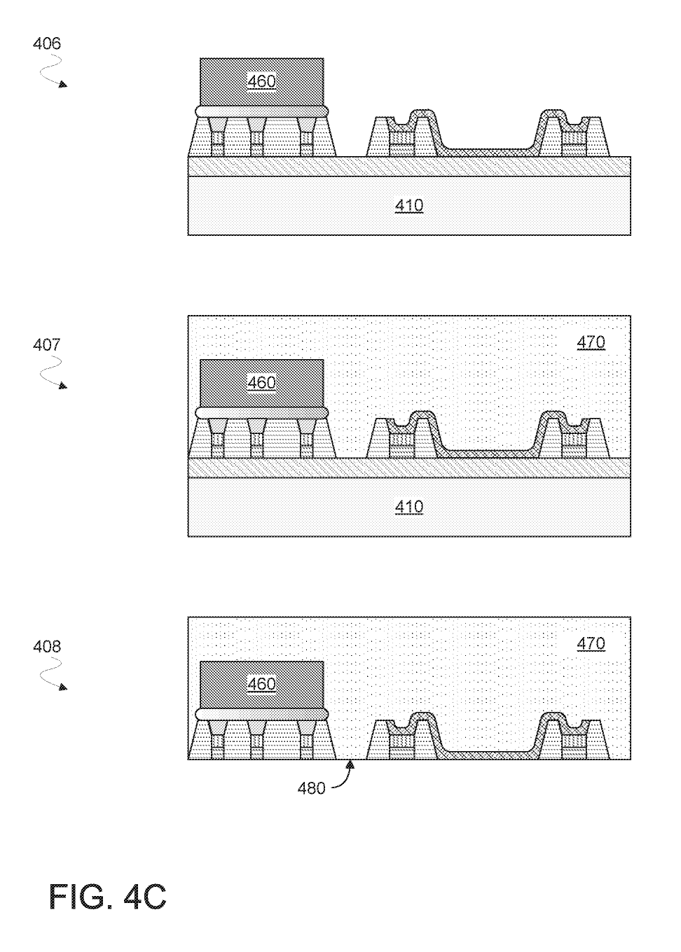

FIGS. 4A-4C show various stages 400-408 of processing to package flexible circuit structures according to an embodiment. Stages 400-408 may package circuit structures having one or more features of device 102, for example. In an embodiment, such processing includes some or all features of method 200.

Referring now to stage 400, a patterned mask 414 may be formed on a release layer 412 which, in turn is disposed on a substrate 410. For example, patterned mask 414, release layer 412 and substrate 410 may have features corresponding to those of patterned mask 314, release layer 312 and substrate 310. As shown at stage 401, patterned mask 414 may be stripped or otherwise removed after metallization processes to form patterned metal layer 416 on release layer 412. Patterned metal layer 416 may comprise successive levels of copper/nickel/copper, successive levels of gold/nickel/copper, successive levels of copper/gold/nickel/copper or any of various other arrangements of one or more metal layers.

Referring now to stage 402, a layer 420 of one or more insulator materials may be deposited over patterned metal layer 416. Pattern processing may then be performed to generate patterned insulator layer 422 from layer 420, as shown in stage 403. Patterned insulator layer 422 may expose one or more regions of patterned metal layer 416—e.g., wherein such regions include contacts 430, 434. Although some embodiments are not limited in this regard, a height of some or all of patterned insulator layer 422 may be greater than a height of contact 430 and/or a height of contact 434.

As illustrated by stages 404, 405, an interconnect structure 450 may be fabricated to couple contacts 430, 434 to each other. By way of illustration and not limitation, a patterned dry film resist 440 may be deposited on select portions of patterned insulator layer 422—e.g., wherein a cavity 442 formed by dry film resist 440 leaves region 432 and contacts 430, 434 exposed. Metallization may then be electroplated or otherwise deposited into cavity 442 to form an interconnect structure 450.

Subsequent to (or in some embodiments, prior to) fabrication of interconnect structure 450, one or more circuit components may be variously coupled directly or indirectly to respective ones of contacts 430, 434. For example, a circuit component 460 may be coupled, at stage 406, to respective contacts of patterned metal layer 416. Circuit component 460 may include one or more passive circuit elements and/or active circuit elements—e.g., wherein circuit component 460 comprises an IC chip.

At stage 407, a mold compound 470 may be injection molded or otherwise disposed on or around interconnect structure 450. In an embodiment, interconnect structure 450 includes a minimum point 456 in region 432, where the minimum point 456 is closer to release layer 412 than is either of points 452, 454 where interconnect structure 450 is coupled to contacts 430, 434, respectively. Deposition and curing of mold compound 470 may form a flexible package structure on the circuits structures disposed on release layer 412. As shown at stage 408, substrate 410 and release layer 412 may be separated to expose a side 480 of the resulting packaged circuit device.

The flexible packaged circuit device formed at one of stages 308, 408 may have any of a variety of configurations of an interconnect structure to other circuit structure (such as conductive contacts coupled thereto) and/or to a mold package which encapsulates some or all of the interconnect structure and other circuit structure. By way of illustration and not limitation, mold compound 350 may adjoin interconnect structure 340 along all of the linear extent of interconnect structure 340 from conductive contact 324 to conductive contact 326. A cross-section of interconnect structure 340 which includes maximum 342 (or, alternatively, which includes a minimum point) may surrounded by—and in some embodiments, adjoined by—mold compound 350. Conductive contact 324 may couple interconnect structure 340 to a metal layer (e.g., extending under circuit components 330, 332) including one or more traces that are to exchange various signals and/or voltages along respective paths that are in parallel with the flat plane in which side 362 extends. Alternatively or in addition, conductive contact 326 may couple interconnect structure 340 to another metal layer that is similarly to communicate signals and/or voltages along respective paths that are in parallel with the flat plane. In an embodiment, any other circuit component coupled to interconnect structure 340 is so coupled via one of contacts 324, 326. For example, any signal or voltage exchanged via interconnect structure 340 may be exchanged also by conductive contact 324 and by conductive contact 326.

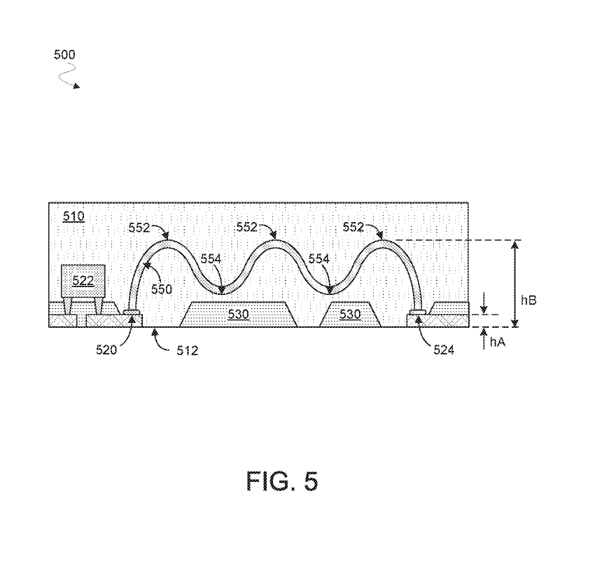

FIG. 5 shows a cross-sectional view of a flexible circuit device 500 according to another embodiment. Flexible circuit device 500 may include some or all features of one of devices 100, 102, for example. Fabrication of flexible circuit device 500 may include operations of method 200—e.g., where such operations include processing such as that represented by stages 300-308 or stages 400-408.

Flexibility of structures in device 500 may accommodate a configuration of device 500 such that a side 512 of device 500 extends in a flat plane. In the illustrative embodiment shown, device 500 includes conductive contacts 520, 524 and a flexible package 510. One or more other circuit structures (such as the illustrative circuit component 522) may be variously coupled, directly or indirectly, each to a respective one of contacts 520, 524. In an embodiment, an interconnect structure 550 couple contacts 520, 524 to each other—e.g., wherein interconnect structure 550 includes arched, bent, angled or otherwise curved portions which form multiple corrugations.

The illustrative arches of interconnect structure 550 are just one example of corrugation structures that, with respect to some reference plane when device 500 is laid flat (e.g., not bent), form multiple local minima and/or multiple local maxima. For example, interconnect structure 550 may include multiple maxima 552, each of which is (at least for a corresponding surrounding portion of interconnect structure 550) a furthest point from a side 512 of device. Interconnect structure 550 may include multiple minima 554, each of which is (at least for a corresponding surrounding portion of interconnect structure 550) a respective closest point to side 512.

A height (z-axis) range spanned by interconnect structure 550 may be equal to a difference (hB−hA) between a height hB of a highest one of interconnect maxima 552 and a lowest height hA at which interconnect structure 550 couples to one of contacts 520, 524. In another embodiment, the height range may be more than the difference (hB−hA)—e.g., wherein some or all of the one or more minima 554 are closer to side 512 than either of contacts 520, 524. Although some embodiments are not limited in this regard, interconnect structure 550 may extend over and span one or more structures (e.g., including the illustrative patterned insulation structures 530) which are disposed between contacts 520, 524.

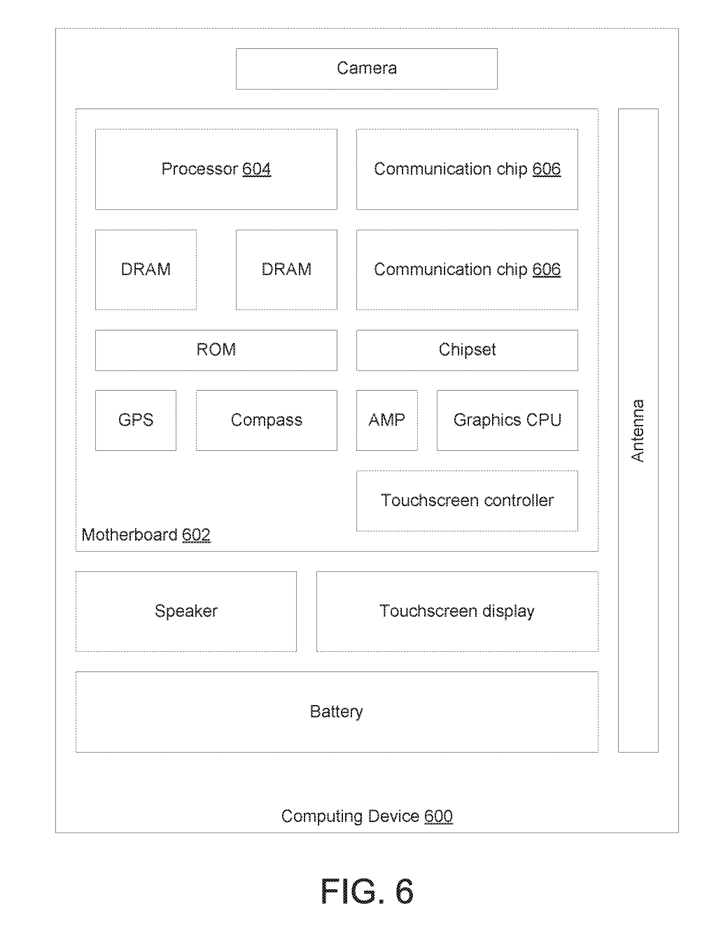

FIG. 6 illustrates a computing device 600 in accordance with one embodiment. The computing device 600 houses a board 602. The board 602 may include a number of components, including but not limited to a processor 604 and at least one communication chip 606. The processor 604 is physically and electrically coupled to the board 602. In some implementations the at least one communication chip 606 is also physically and electrically coupled to the board 602. In further implementations, the communication chip 606 is part of the processor 604.

Depending on its applications, computing device 600 may include other components that may or may not be physically and electrically coupled to the board 602. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 606 enables wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 606 may implement any of a number of wireless standards or protocols, including but not limited to Wi-Fi (IEEE 802.11 family), WiMAX (IEEE 802.16family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 600 may include a plurality of communication chips 606. For instance, a first communication chip 606 may be dedicated to shorter range wireless communications such as Wi-Fi and Bluetooth and a second communication chip 606 may be dedicated to longer range wireless communications such as GPS, EDGE, GPRS, CDMA, WiMAX, LTE, Ev-DO, and others.

The processor 604 of the computing device 600 includes an integrated circuit die packaged within the processor 604. The term “processor” may refer to any device or portion of a device that processes electronic data from registers and/or memory to transform that electronic data into other electronic data that may be stored in registers and/or memory. The communication chip 606 also includes an integrated circuit die packaged within the communication chip 606.

In various implementations, the computing device 600 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 600 may be any other electronic device that processes data.

Some embodiments may be provided as a computer program product, or software, that may include a machine-readable medium having stored thereon instructions, which may be used to program a computer system (or other electronic devices) to perform a process according to an embodiment. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

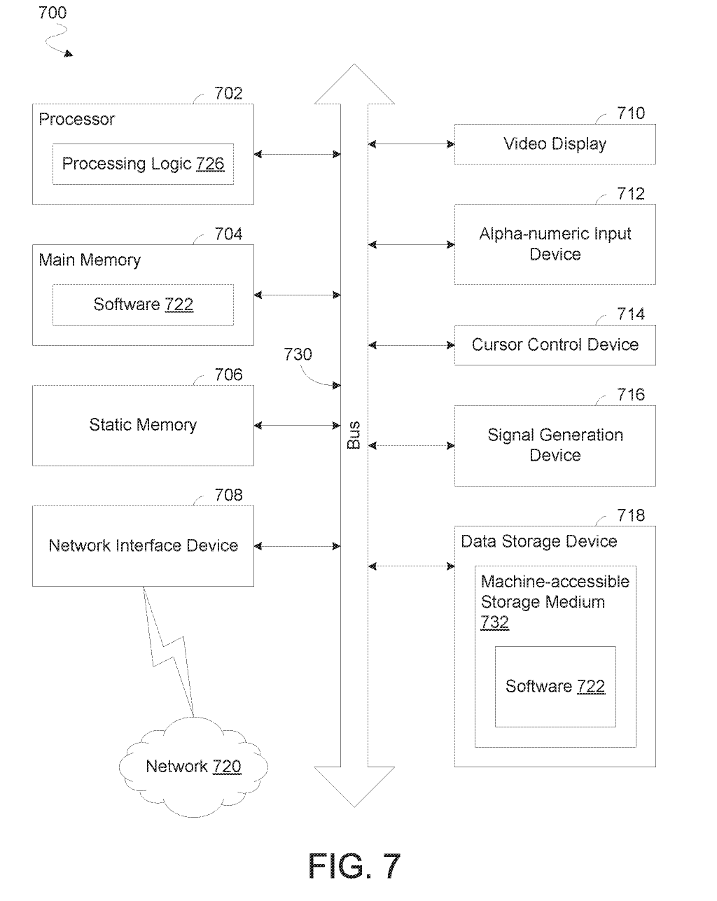

FIG. 7 illustrates a diagrammatic representation of a machine in the exemplary form of a computer system 700 within which a set of instructions, for causing the machine to perform any one or more of the methodologies described herein, may be executed. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies described herein.

The exemplary computer system 700 includes a processor 702, a main memory 704 (e.g., read-only memory (ROM), flash memory, dynamic random access memory (DRAM) such as synchronous DRAM (SDRAM) or Rambus DRAM (RDRAM), etc.), a static memory 706 (e.g., flash memory, static random access memory (SRAM), etc.), and a secondary memory 718 (e.g., a data storage device), which communicate with each other via a bus 730.

Processor 702 represents one or more general-purpose processing devices such as a microprocessor, central processing unit, or the like. More particularly, the processor 702 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 702 may also be one or more special-purpose processing devices such as an application specific integrated circuit (ASIC), a field programmable gate array (FPGA), a digital signal processor (DSP), network processor, or the like. Processor 702 is configured to execute the processing logic 726 for performing the operations described herein.

The computer system 700 may further include a network interface device 708. The computer system 700 also may include a video display unit 710 (e.g., a liquid crystal display (LCD), a light emitting diode display (LED), or a cathode ray tube (CRT)), an alphanumeric input device 712 (e.g., a keyboard), a cursor control device 714 (e.g., a mouse), and a signal generation device 716 (e.g., a speaker).

The secondary memory 718 may include a machine-accessible storage medium (or more specifically a computer-readable storage medium) 732 on which is stored one or more sets of instructions (e.g., software 722) embodying any one or more of the methodologies or functions described herein. The software 722 may also reside, completely or at least partially, within the main memory 704 and/or within the processor 702 during execution thereof by the computer system 700, the main memory 704 and the processor 702 also constituting machine-readable storage media. The software 722 may further be transmitted or received over a network 720 via the network interface device 708.

While the machine-accessible storage medium 732 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any of one or more embodiments. The term “machine-readable storage medium” shall accordingly be taken to include, but not be limited to, solid-state memories, and optical and magnetic media.

In one implementation, a flexible circuit device comprises a first conductive contact and a second conductive contact, an interconnect structure coupled to the first conductive contact and to the second conductive contact, and a flexible package encapsulating a first portion of the interconnect structure. While a first side of the flexible circuit device is positioned to extend in a first flat plane the first conductive contact is disposed over a first region of the first side, the second conductive contact is disposed over a second region of the first side, the first portion is disposed over a third region of the first side, the third region between the first region and the second region, wherein, with respect to a distance from the first flat plane, the first portion to include a maximum of the interconnect structure or a minimum of the interconnect structure, and a range spanned by the interconnect structure along a line orthogonal to the first flat plane is at least two times an average height of the interconnect structure.

In an embodiment, the interconnect structure extends only partially through a mold compound of the flexible package in the direction orthogonal to the first flat plane. In another embodiment, the interconnect structure includes multiple local maxima or multiple local minima. In another embodiment, the first conductive contact is formed in or on a first insulator structure, wherein the interconnect structure extends past an edge of the first insulator structure. In another embodiment, a mold compound of the flexible package surrounds the first portion. In another embodiment, a mold compound of the flexible package adjoins the interconnect structure along an entire length of the interconnect structure from the first conductive contact to the second conductive contact. In another embodiment, the range spanned by the interconnect structure along the line orthogonal to the first flat plane is at least five times the average height. In another embodiment, the interconnect structure include a braided conductor.

In another implementation, a method of fabricating a flexible circuit device, the method comprises forming a first conductive contact over a first region of a first flat plane, wherein the first conductive contact is at a first distance from the first flat plane, forming a second conductive contact over a second region of a first flat plane, wherein the second conductive contact is at a second distance from the first flat plane, coupling the first conductive contact to the second conductive contact with an interconnect structure including a first portion over a third region of the first flat plane, the third region between the first region and the second region, encapsulating the first portion with a mold compound, and curing the mold compound to form a flexible package, wherein, with respect to a distance from the first flat plane, the first portion includes a maximum of the interconnect structure or a minimum of the interconnect structure, wherein a range spanned by the interconnect structure along a line orthogonal to the first flat plane is at least two times an average height of the interconnect structure.

In an embodiment, coupling the first conductive contact to the second conductive contact includes wire bonding the interconnect structure to one of the first conductive contact and the second conductive contact. In another embodiment, coupling the first conductive contact to the second conductive contact includes performing metal deposition to fabricate the interconnect structure. In another embodiment, the interconnect structure extends only partially through the mold compound in the direction orthogonal to the first flat plane. In another embodiment, the interconnect structure includes multiple local maxima or multiple local minima. In another embodiment, the first conductive contact is formed in or on a first insulator structure, wherein the interconnect structure extends past an edge of the first insulator structure. In another embodiment, the mold compound surrounds the first portion. In another embodiment, the mold compound adjoins the interconnect structure along an entire length of the interconnect structure from the first conductive contact to the second conductive contact. In another embodiment, the range spanned by the interconnect structure along the line orthogonal to the first flat plane is at least five times the average height. In another embodiment, the interconnect structure include a braided conductor.

In another implementation, a system comprises a flexible circuit device comprising a first conductive contact and a second conductive contact, an interconnect structure coupled to the first conductive contact and to the second conductive contact, and a flexible package encapsulating a first portion of the interconnect structure. While a first side of the flexible circuit device is positioned to extend in a first flat plane, the first conductive contact is disposed over a first region of the first side, the second conductive contact is disposed over a second region of the first side, the first portion is disposed over a third region of the first side, the third region between the first region and the second region, wherein, with respect to a distance from the first flat plane, the first portion to include a maximum of the interconnect structure or a minimum of the interconnect structure, and a range spanned by the interconnect structure along a line orthogonal to the first flat plane is at least two times an average height of the interconnect structure. The system further comprises a display coupled to the first flexible circuit device, the display to generate an image based on a signal or a voltage exchanged via the interconnect.

In an embodiment, the interconnect structure extends only partially through a mold compound of the flexible package in the direction orthogonal to the first flat plane. In another embodiment, the interconnect structure includes multiple local maxima or multiple local minima. In another embodiment, the first conductive contact is formed in or on a first insulator structure, wherein the interconnect structure extends past an edge of the first insulator structure. In another embodiment, a mold compound of the flexible package surrounds the first portion. In another embodiment, a mold compound of the flexible package adjoins the interconnect structure along an entire length of the interconnect structure from the first conductive contact to the second conductive contact. In another embodiment, the range spanned by the interconnect structure along the line orthogonal to the first flat plane is at least five times the average height. In another embodiment, the interconnect structure include a braided conductor.

Techniques and architectures for providing flexible circuit structures are described herein. In the above description, for purposes of explanation, numerous specific details are set forth in order to provide a thorough understanding of certain embodiments. It will be apparent, however, to one skilled in the art that certain embodiments can be practiced without these specific details. In other instances, structures and devices are shown in block diagram form in order to avoid obscuring the description.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

Some portions of the detailed description herein are presented in terms of algorithms and symbolic representations of operations on data bits within a computer memory. These algorithmic descriptions and representations are the means used by those skilled in the computing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the discussion herein, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Certain embodiments also relate to apparatus for performing the operations herein. This apparatus may be specially constructed for the required purposes, or it may comprise a general purpose computer selectively activated or reconfigured by a computer program stored in the computer. Such a computer program may be stored in a computer readable storage medium, such as, but is not limited to, any type of disk including floppy disks, optical disks, CD-ROMs, and magnetic-optical disks, read-only memories (ROMs), random access memories (RAMs) such as dynamic RAM (DRAM), EPROMs, EEPROMs, magnetic or optical cards, or any type of media suitable for storing electronic instructions, and coupled to a computer system bus.

The algorithms and displays presented herein are not inherently related to any particular computer or other apparatus. Various general purpose systems may be used with programs in accordance with the teachings herein, or it may prove convenient to construct more specialized apparatus to perform the required method steps. The required structure for a variety of these systems will appear from the description herein. In addition, certain embodiments are not described with reference to any particular programming language. It will be appreciated that a variety of programming languages may be used to implement the teachings of such embodiments as described herein.

Besides what is described herein, various modifications may be made to the disclosed embodiments and implementations thereof without departing from their scope. Therefore, the illustrations and examples herein should be construed in an illustrative, and not a restrictive sense. The scope of the invention should be measured solely by reference to the claims that follow.

1.-25. (canceled)

26. A flexible circuit device comprising:
a first conductive contact and a second conductive contact;
an interconnect structure coupled to the first conductive contact and to the second conductive contact; and
a flexible package encapsulating a first portion of the interconnect structure;
wherein, while a first side of the flexible circuit device is positioned to extend in a first flat plane:
the first conductive contact is disposed over a first region of the first side;
the second conductive contact is disposed over a second region of the first side;
the first portion is disposed over a third region of the first side, the third region between the first region and the second region, wherein, with respect to a distance from the first flat plane, the first portion to include a maximum of the interconnect structure or a minimum of the interconnect structure; and
a range spanned by the interconnect structure along a line orthogonal to the first flat plane is at least two times an average height of the interconnect structure.

27. The flexible circuit device of claim 26, wherein the interconnect structure extends only partially through a mold compound of the flexible package in the direction orthogonal to the first flat plane.

28. The flexible circuit device of claim 26, wherein the interconnect structure includes multiple local maxima or multiple local minima.

29. The flexible circuit device of claim 26, wherein the first conductive contact is formed in or on a first insulator structure, wherein the interconnect structure extends past an edge of the first insulator structure.

30. The flexible circuit device of claim 26, wherein a mold compound of the flexible package surrounds the first portion.

31. The flexible circuit device of claim 26, wherein a mold compound of the flexible package adjoins the interconnect structure along an entire length of the interconnect structure from the first conductive contact to the second conductive contact.

32. The flexible circuit device of claim 26, wherein the range spanned by the interconnect structure along the line orthogonal to the first flat plane is at least five times the average height.

33. The flexible circuit device of claim 26, wherein the interconnect structure includes a braided conductor.

34. A method of fabricating a flexible circuit device, the method comprising:
forming a first conductive contact over a first region of a first flat plane, wherein the first conductive contact is at a first distance from the first flat plane;
forming a second conductive contact over a second region of a first flat plane, wherein the second conductive contact is at a second distance from the first flat plane;
coupling the first conductive contact to the second conductive contact with an interconnect structure including a first portion over a third region of the first flat plane, the third region between the first region and the second region;
encapsulating the first portion with a mold compound;
curing the mold compound to form a flexible package, wherein, with respect to a distance from the first flat plane, the first portion includes a maximum of the interconnect structure or a minimum of the interconnect structure, wherein a range spanned by the interconnect structure along a line orthogonal to the first flat plane is at least two times an average height of the interconnect structure.

35. The method of claim 34, wherein coupling the first conductive contact to the second conductive contact includes wire bonding the interconnect structure to one of the first conductive contact and the second conductive contact.

36. The method of claim 34, wherein coupling the first conductive contact to the second conductive contact includes performing metal deposition to fabricate the interconnect structure.

37. The method of claim 34, wherein the interconnect structure includes multiple local maxima or multiple local minima.

38. The method of claim 34, wherein the mold compound surrounds the first portion.

39. The method of claim 34, wherein the range spanned by the interconnect structure along the line orthogonal to the first flat plane is at least five times the average height.

40. The method of claim 34, wherein the interconnect structure includes a braided conductor.

41. A system comprising:
a flexible circuit device comprising:
a first conductive contact and a second conductive contact;
an interconnect structure coupled to the first conductive contact and to the second conductive contact; and
a flexible package encapsulating a first portion of the interconnect structure;
wherein, while a first side of the flexible circuit device is positioned to extend in a first flat plane:
the first conductive contact is disposed over a first region of the first side;
the second conductive contact is disposed over a second region of the first side;
the first portion is disposed over a third region of the first side, the third region between the first region and the second region, wherein, with respect to a distance from the first flat plane, the first portion to include a maximum of the interconnect structure or a minimum of the interconnect structure; and
a range spanned by the interconnect structure along a line orthogonal to the first flat plane is at least two times an average height of the interconnect structure; and
a display coupled to the first flexible circuit device, the display to generate an image based on a signal or a voltage exchanged via the interconnect.

42. The system of claim 41, wherein the interconnect structure includes multiple local maxima or multiple local minima.

43. The system of claim 41, wherein a mold compound of the flexible package surrounds the first portion.

44. The system of claim 41, wherein the range spanned by the interconnect structure along the line orthogonal to the first flat plane is at least five times the average height.

45. The system of claim 41, wherein the interconnect structure includes a braided conductor.
